(19) United States
(12) Patent Application Publication
(10) Pub. No.: US 2008/0217618 A1
(43) Pub. Date: Sep. 11, 2008

(54) Thin Film Circuits

(75) Inventor: Steven C. Deane, Redhill (GB)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/996,591

(22) PCT Filed: Jul. 21, 2006
(86) PCT No.: PCT/IB2006/052502

§ 371 Date: Jan. 24, 2008

(30) Foreign Application Priority Data
Jul. 25, 2005 (EP) 05106819.5

(51) Int. Cl. H01L 27/088

(52) U.S. Cl. 257/59; 257/E27.009

(57) ABSTRACT

A thin film circuit comprises a plurality of thin film transistors, each having a light shield portion (60) which is electrically isolated from the source (72), drain (70) and gate (76) electrodes. The light shield portion comprises a first, drain overlap portion in which the light shield portion overlaps the drain conductor (70), a second, source overlap portion in which the light shield portion overlaps the source conductor (72), and a third, gate overlap portion in which the light shield portion overlaps the gate conductor (76) only. In one embodiment, at least ⅔ of the light shield portion area comprises the gate overlap portion. In another embodiment, one of the source and drain overlap portions has at least 1.5 times the area of the other of the source and drain overlap portions. The use of an electrically floating light shield simplifies the layer construction and design. The arrangement of overlap areas provides controlled capacitive coupling between the light shield and the transistor terminals, and this can suppress the effect of the light shield voltage floating to levels which impact on circuit performance.

This invention relates to thin film circuits, in particular circuits including thin film transistors.

One widespread use of thin film circuits is for active matrix liquid crystal displays, and the invention is of particular benefit in the design and manufacture of the transistor substrate, known as the active plate, used in such displays.

A liquid crystal display typically comprises an active plate and a passive plate between which liquid crystal material is sandwiched. The active plate comprises an array of transistor switching devices, typically with one transistor associated with each pixel of the display. Each pixel is also associated with a pixel electrode on the active plate to which a signal is applied for controlling the brightness of the individual pixel.

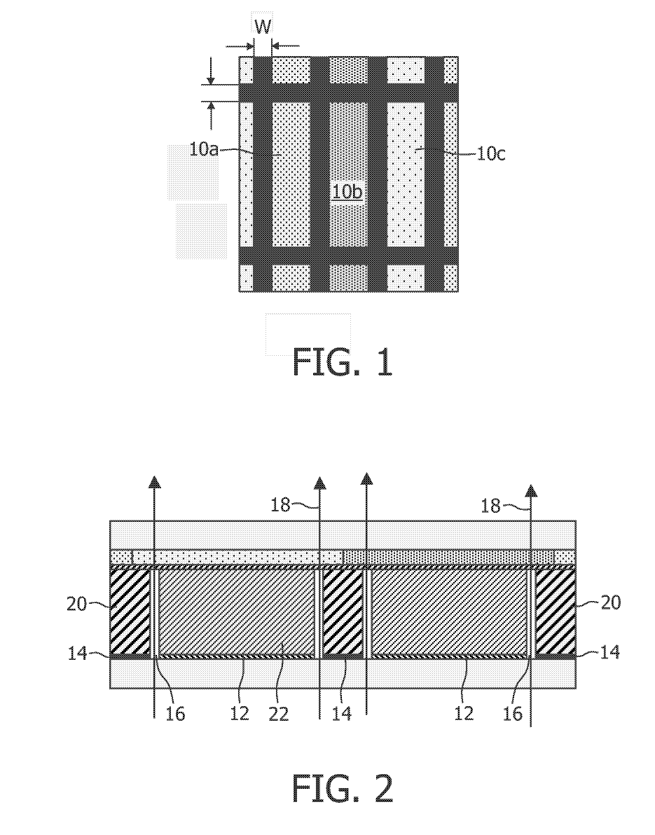

FIG. 1 shows a typical view of the transmissive areas of an AMLCD. The basic pixels are square but divided into three vertical sub-pixels 10 coloured red 10a, green 10b and blue 10c.

A large area of the active plate is at least partially transparent, and this is required because the display is typically illuminated by a backlight. Mainly, the areas covered by the opaque row and column conductors are the only opaque parts of the plate. If the pixel electrode does not cover the transparent area, then there will be an area of liquid crystal material not modulated by the pixel electrode but which does receive light from the backlight. This reduces the contrast ratio and blackness of the display.

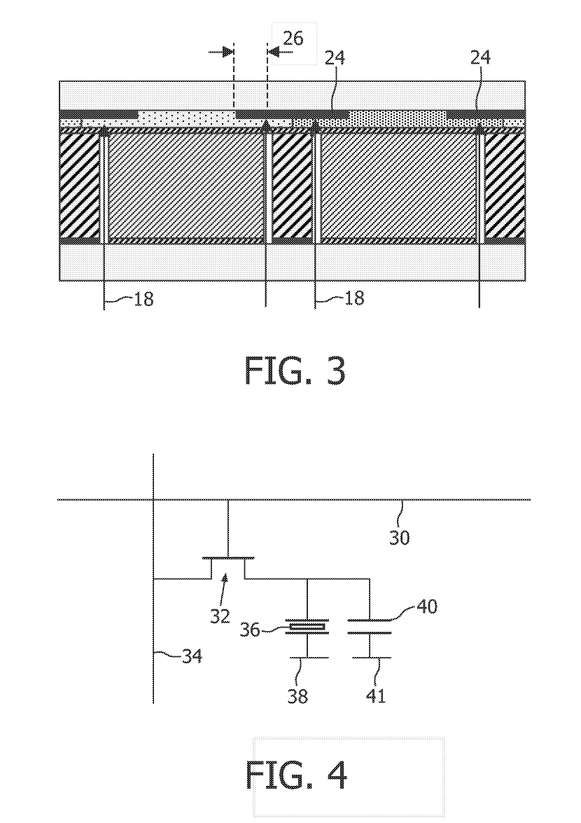

FIG. 2 shows an arrangement in which the pixel electrodes 12 are provided between the column conductors 14, so that there is a gap 16 between the pixels and columns on the active plate through which unmodulated light 18 can pass. Regions 20 of the LC layer are shielded by the columns 14 whereas regions 22 are modulated by the pixel electrodes 12. This is a so-called “standard” display. In such a display, a black mask layer is typically provided for shielding these areas of the active plate, and additionally to shield the transistors as their operating characteristics are light-dependent. Conventionally, the black mask layer has been located on the passive plate of the active matrix cell. Plate to plate alignment during cell manufacture is less accurate than layer to layer alignment on a substrate. This means that the black mask must be comparatively large to ensure that it blocks stray light at the edge of pixels. FIG. 3 shows a cell with a black mask 24 on the passive plate and the required overlap is shown as 26. The width of the columns of black mask layer 24 define the width W in FIG. 1.

This overlap reduces the aperture of the display pixels, which reduces the power efficiency of the display. This is particularly undesirable for battery-operated devices, such as portable products.

FIG. 4 shows the electrical components which make up the sub pixels shown in FIG. 1. A row conductor 30 is connected to the gate of a TFT 32, and a column electrode 34 is coupled to the source. The liquid crystal material provided over the pixel effectively defines a liquid crystal cell 36 which extends between the drain of the transistor 32 and a common ground plane 38. The ground plane 38 is defined by the passive plate and the other terminal of the LC cell is defined by the pixel electrodes 12. A pixel storage capacitor 40 is connected between the drain of the transistor 32 and the row conductor associated with an adjacent row of pixels or else to a separate line 41.

It has been proposed to use layers of the active plate to provide the required masking function. For example, one proposal is to define the pixel electrodes 12 to overlap the row and column conductors 30,34, so that there is no gap between the row and column conductors and the pixel electrodes, which would otherwise need to be shielded. This results in a high aperture pixel, and is called a Field Shielded Pixel (FSP) design.

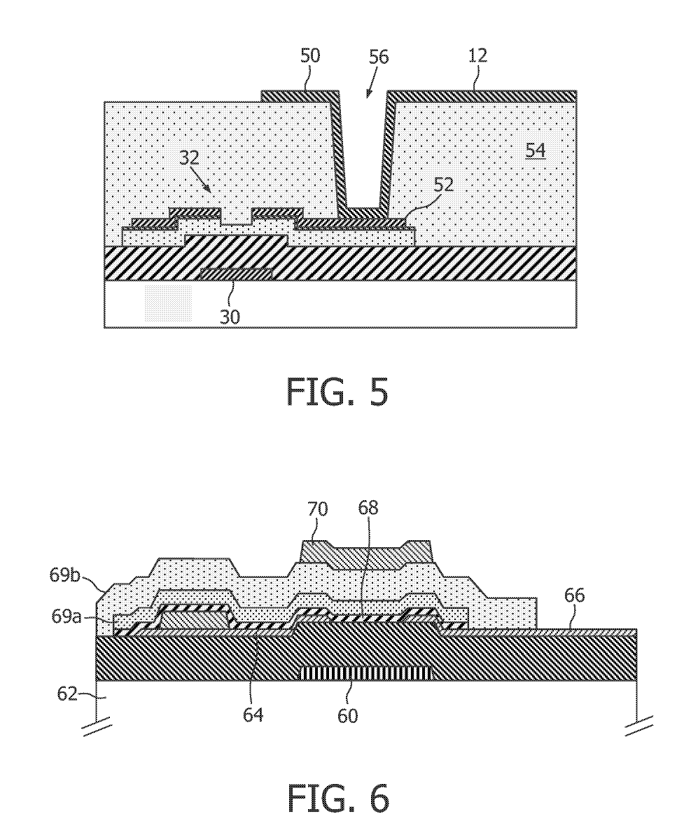

FIG. 5 shows a cross-section through the TFT of a FSP panel.

The pixel electrode 50 overlaps the row conductor 30 as shown in FIG. 5 and also overlaps the column conductor 34. The row and column conductors thus block the passage of light.

In the bottom gate example of FIG. 5, the gate electrode provides shielding of the channel of the TFT from the backlight illumination (beneath the substrate). However, ambient light can reach the TFT channel from above. In a top gate TFT design, there is no shielding of the TFT channel from the backlight illumination. Thus, even when pixel designs avoid the need for a black mask layer for shielding unmodulated regions of the display layer, a light shield is still desirable for shielding the TFT channel.

It has been proposed to provide a light shield beneath the transistor layers to shield the TFT channel from the backlight illumination. FIG. 6 shows a top gate TFT structure in which a light shield layer is provided beneath the TFT structure.

The light shield 60 is provided over the substrate 62, and has a shape corresponding to the gate electrode, and is beneath the TFT channel. FIG. 6 shows the source 64, drain 66, transistor channel 68 and two gate insulator layers 69a, 69b, with the gate electrode shown as 70.

The light shield can be at a fixed or floating potential, and is placed symmetrically with respect to the source and drain 64,66 of the TFT. This can result in unwanted effects at high drain biases, where the TFT leakage current increases.

If the light shield is at a fixed potential, i.e. connected to an external voltage source, then it can interfere with the switching of the TFT. This can result in increased threshold voltage, reduced apparent mobility, or increased leakage currents, depending on the voltage. One proposed solution to this problem is to connect directly the light shield to the gate electrode, but this introduces extra process steps, increasing the cost of the active matrix device.

The light shield may instead be left at a floating potential. This may be appropriate for use of the TFT as a pixel TFT in liquid crystal displays, as the worst-case source-drain voltage can (depending on the technology) be kept to the order of 10V. When higher source-drain voltages are required, this can result in unacceptable changes to the TFT performance characteristics. Some pixel designs and technologies may require these higher voltages, and the integration of other functions onto the display substrate can also require operation at higher voltages.

In these higher voltage applications, the floating light shield can reach a sufficiently positive voltages when a high source-drain bias is applied, that it partially turns the TFT channel on, resulting in a leakage current.

According to a first aspect of the invention, there is provided a thin film circuit comprising a plurality of thin film transistors at least some of which comprise:

a transistor channel;

a gate electrode on one vertical side of the channel;

source and drain electrodes; and

a light shield portion on the other vertical side of the channel aligned with the transistor channel,

wherein the light shield portion is electrically isolated from the source, drain and gate electrodes, and wherein the light shield portion comprises a first, drain overlap portion in which the light shield portion overlaps the drain conductor, a second, source overlap portion in which the light shield portion overlaps the source conductor, and a third, gate overlap portion in which the light shield portion overlaps the gate conductor only,

and wherein at least ⅔ of the light shield portion area comprises the gate overlap portion.

This circuit configuration uses a light shield layer to shield the TFT channel. The use of an electrically floating light shield simplifies the layer construction and design. The use of a relatively large gate overlap area provides capacitive coupling between the light shield and the gate, and this can suppress the effect of the light shield voltage floating to levels which impact on circuit performance.

Preferably, at least 80%, or even 90% of the light shield portion area comprises the gate overlap portion.

According to a second aspect of the invention, there is provided a thin film circuit comprising a plurality of thin film transistors at least some of which comprise:

a transistor channel;

a gate electrode on one vertical side of the channel;

source and drain electrodes; and

a light shield portion on the other vertical side of the channel aligned with the transistor channel,

wherein the light shield portion is electrically isolated from the source, drain and gate electrodes, and wherein the light shield portion comprises a first, drain overlap portion in which the light shield portion overlaps the drain conductor, a second, source overlap portion in which the light shield portion overlaps the source conductor, and a third, gate overlap portion in which the light shield portion overlaps the gate conductor only,

and wherein one of the source and drain overlap portions has at least 1.5 times the area of the other of the source and drain overlap portions.

This circuit configuration again uses a light shield layer to shield the TFT channel, with an electrically floating light shield to simplify the layer construction and design. The use of asymmetric overlap areas of the light shield with the source and drain electrodes can again improve circuit performance by reducing TFT leakage currents.

The source overlap portion is preferably at least 1.5, or at least 2 times larger than the drain overlap portion, and this enables a reduction in high drain bias TFT leakage.

In either aspect of the invention, each of the plurality of thin film transistors may comprise a top gate transistor, with the light shield portion beneath the transistor channel, or a bottom gate transistor, with the light shield portion above the transistor channel.

Each of the plurality of thin film transistors may for example comprise an amorphous silicon transistor, or a low temperature polysilicon transistor.

The invention can be used in circuits comprising an array of active matrix pixel circuits provided on a common substrate, each pixel circuit comprising at least one of the plurality of the thin film transistors. The transistor designs can also be used for drive circuitry provided on the common substrate

The invention can be used in active matrix display devices.

Examples of the invention will now be described in detail with reference to the accompanying drawings, in which:

FIG. 1 shows a plan view of a known colour AMLCD;

FIG. 2 shows a cross section through a known standard AMLCD;

FIG. 3 shows how a black mask layer is used to improve the performance of the AMLCD of FIG. 2;

FIG. 4 shows the electrical elements of each pixel;

FIG. 5 shows a known Field Shielded Pixel design, in cross section through the transistor;

FIG. 6 shows a known use of a light shield layer within a pixel circuit layout, in cross section;

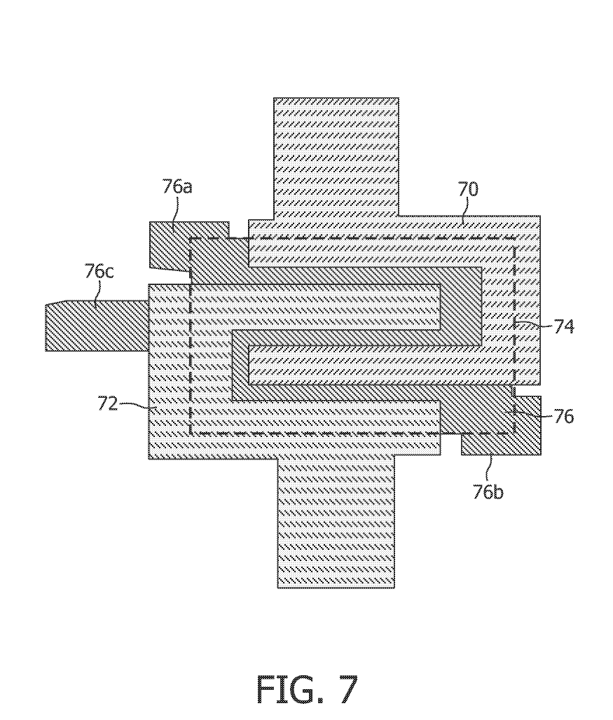

FIG. 7 shows a known thin film transistor layout, in plan view

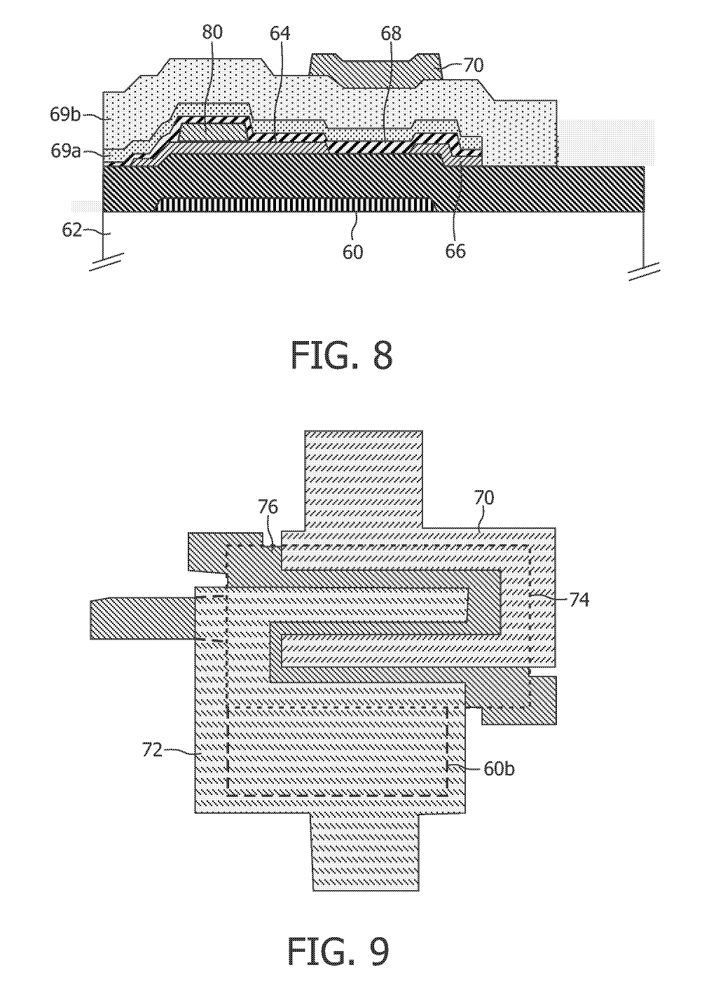

FIG. 8 shows use of a light shield layer within a pixel circuit layout of the invention, in cross section;

FIG. 9 shows a first example of thin film transistor layout of the invention, in plan view;

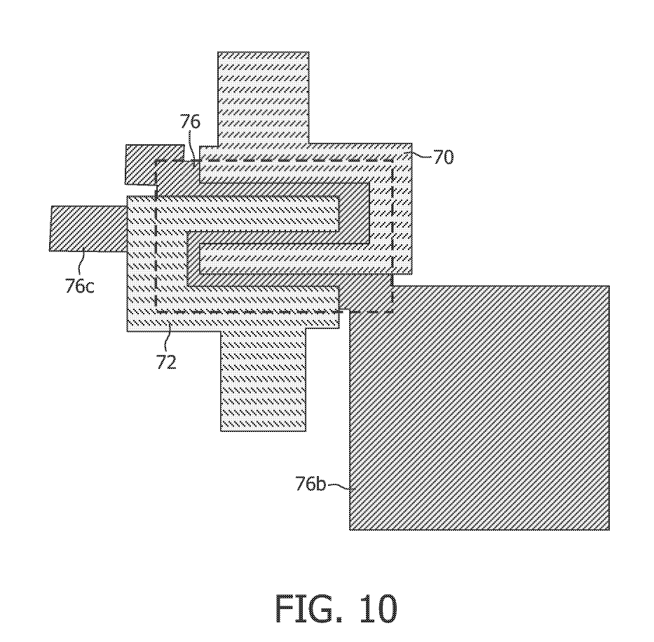

FIG. 10 shows a second example of thin film transistor layout of the invention, in plan view; and

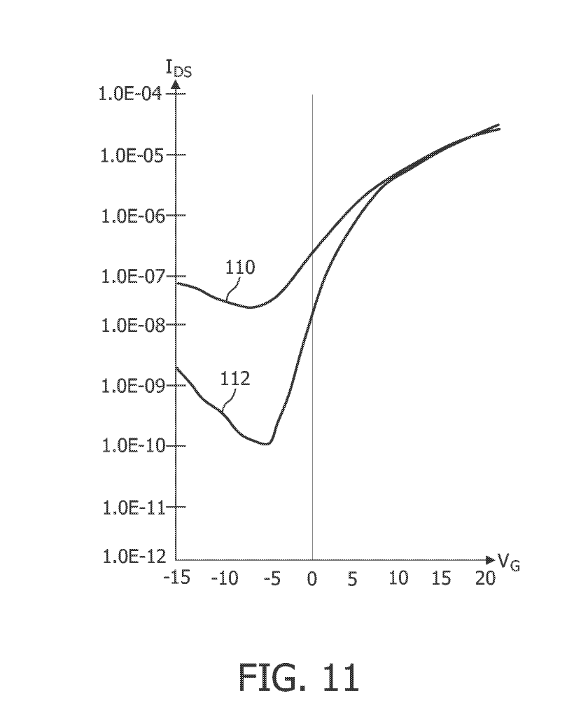

FIG. 11 is used to explain the effect of one implementation of the invention on TFT characteristics;

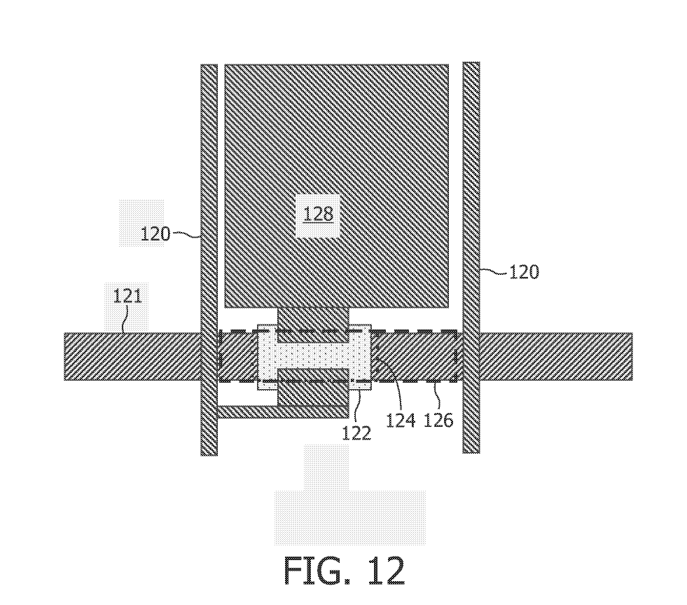

FIG. 12 shows how area under a row conductor can be used to increase a gate overlap area of the light shield;

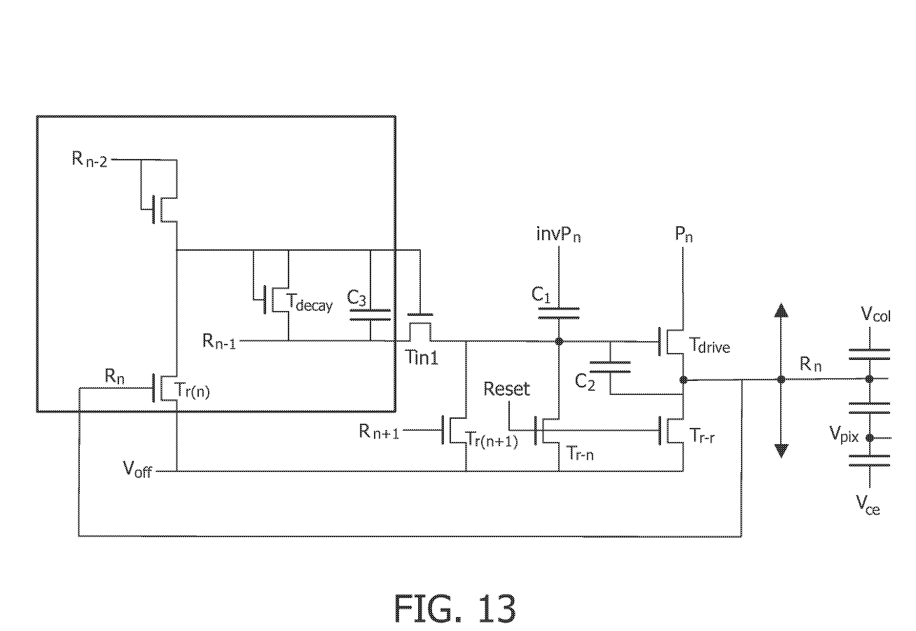

FIG. 13 shows a row driver circuit which to which the invention can be applied;

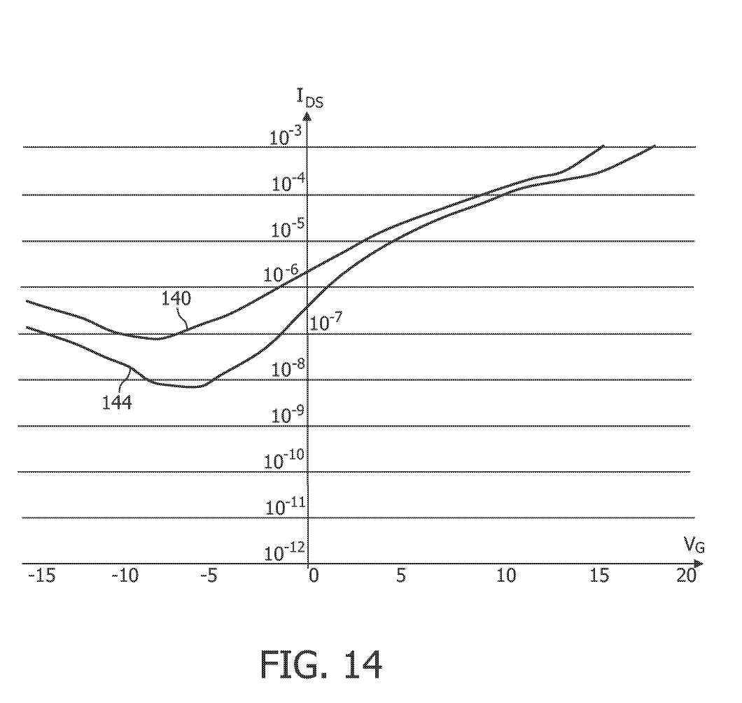

FIG. 14 is a first graph used to explain the effect of the implementation of the invention of FIG. 13 on TFT characteristics;

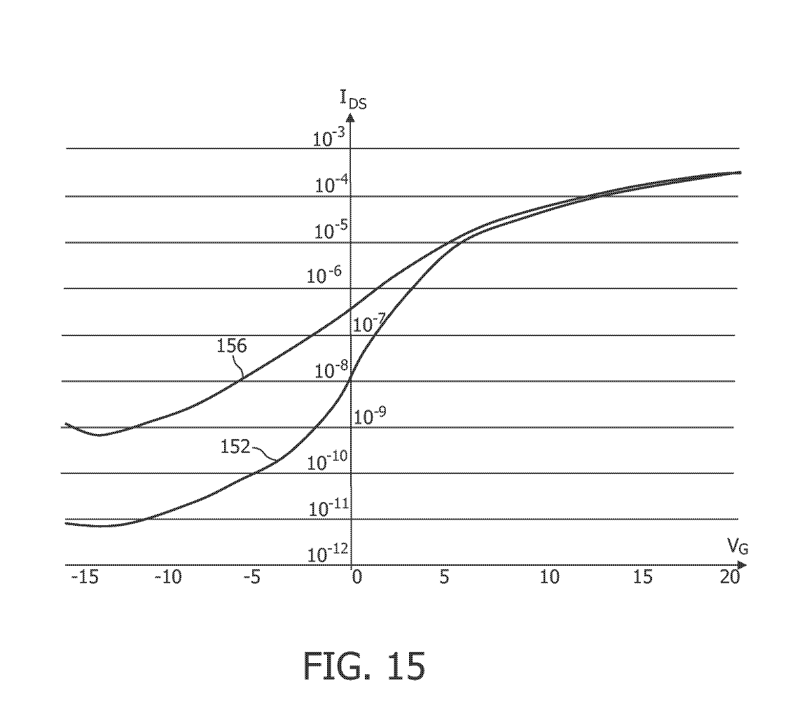

FIG. 15 is a second graph used to explain the effect of the implementation of the invention of FIG. 13 on TFT characteristics; and

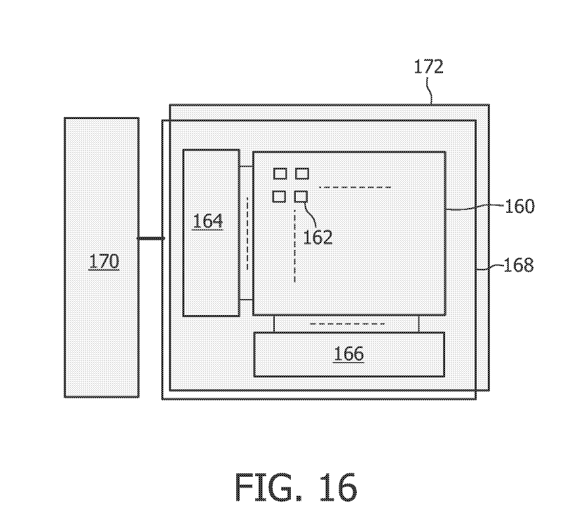

FIG. 16 shows a display device of the invention.

The invention relates to thin film transistor circuits generally, in which light shielding of the transistor channel is desired, and enables a light shield to be used which is electrically floating, namely not electrically connected to the source, drain or gate electrodes. The shape of the light shield with respect to the source, drain and gate electrode is manipulated to provide improved transistor operating characteristics.

One problem which has been identified by the applicant concerning transistor designs with floating light shield electrodes is an unexpected level of leakage current at high drain-source voltage operation of the transistor. There is a requirement for operation with high drain-source voltage in many applications of thin film transistor circuits, for example the pixel transistors of active matrix display devices as well as integrated drive circuits of such devices. The increased leakage current results from the electric potential which is coupled to the light shield, and this in turn is dependent on the capacitive coupling of the light shield to the gate, source and drain transistor electrodes.

In preferred implementations, the invention provides different techniques for reducing the effect of the capacitive coupling to the higher voltage electrode out of the source and drain, so that a high voltage on one of these electrodes has less effect on the light shield electrode. For n-type transistors, which are widely used in amorphous silicon circuits, a high drain-source voltage corresponds to a high drain voltage, whereas in p-type circuits, a large drain-source voltage corresponds to a high source voltage.

The leakage currents can be reduced by introducing additional capacitive coupling to the gate and/or source or drain electrodes.

FIG. 7 shows in simplified schematic form a known thin film transistor layout, in plan view. The diagram is not intended to represent the order of the layers, but is hatched in a way to make the relevant shapes of the different layers most easily discernable.

The drain electrode 70 and source electrode 72 are shown as interleaved comb electrodes. The semiconductor channel has a rectangular shape as shown by reference 74.

The gate electrode 76 corresponds substantially in shape to the semiconductor island, although two corner portions 76a and 76b are shown which are to prevent shorting between the source and drain electrodes through the semiconductor layer in the absence of a controlling electric field. The gate electrode is typically coupled to a row conductor in an active matrix display pixel circuit, and a spur 76c is shown for this purpose.

The light shield corresponds in shape to the gate electrode (but excluding the spur 76c).

The gate electrode and the source/drain electrodes are on opposite sides (in terms of the layer stacking) of the transistor channel. It can be seen that the layout thus defines a stack with a transistor channel, a gate electrode on one vertical side of the channel and source and drain electrodes on the other vertical side of the channel. The term “vertical” is used in this context to refer to the layer position within the stack of thin film layers.

The light shield is on the same vertical side of the channel as the source and drain electrodes, and is aligned with the transistor channel to provide the desired light shielding function.

The layers can be stacked in either order, giving a top gate or bottom gate structure, as desired.

The light shield thus overlaps with the other electrodes in the structure in such a way that different portions can be defined, and which give rise to different capacitive coupling effects. These portions are:

a first, drain overlap portion in which the light shield overlaps the drain conductor. This portion in the example of FIG. 7 corresponds to the part of the drain conductor 70 within the rectangle 74, and is an inverted “C” shape;

a second, source overlap portion in which the light shield portion overlaps the source conductor. This portion in the example of FIG. 7 corresponds to the part of the source conductor 72 within the rectangle 74, and is a “C” shape; and

a third, gate overlap portion in which the light shield portion overlaps the gate conductor only (out of the source, drain and gate conductors). This portion in the example of FIG. 7 corresponds to the remainder of the area within the rectangle 74, together with the corners 76a and 76b.

As outlined above, for implementation with n-type transistors, the invention reduces the relative capacitive coupling to the drain electrode 70.

A first implementation of the invention is shown in cross section in FIG. 8. The same reference numerals are used as in FIG. 6. The change concerns the shape of the light shield 60, which is extended so that there is greater overlap with the source electrode 64 than with the drain electrode 66. In the example of FIG. 8, this has not required modification to the source electrode, as this has an extension to make contact with a column electrode, shown as 80. This implementation of the invention thus increases the light shield to source electrode capacitive coupling.

Of course modification to the source electrode shape may in fact be required, and FIG. 9 shows how the layout of FIG. 7 may be modified to provide the advantages of the invention. The same reference numerals are used as in FIG. 7.

The source electrode 72 is extended to have an increased area, and the light shield is also extended as shown by dotted line 60b. Thus, the light shield follows the outer shape of the dotted lines 60b and 74. This increase in overlap results in increased capacitive coupling to the source electrode, and this prevents the high drain voltage adversely influencing the TFT operating characteristics which would otherwise result from a high voltage on the light shield. This approach increases the size of the source overlap portion as defined above.

This approach has been found to provide significant improvement when the source overlap portion is at least 1.5 times larger than the area of the drain overlap portion.

This multiplier may of course be increased further, for example the source overlap portion can be at least 2 times larger than the drain overlap portion. The particular dimensions chosen will depend on the available layout space and the desired operating characteristics.

A second implementation of the invention is shown in cross section in FIG. 10. The same reference numerals are again used as in FIG. 6. The change again concerns the shape of the light shield 60, but also the gate electrode, which is extended so that there is increased overlap with the gate electrode 64.

In the example of FIG. 10, this has been achieved by increasing the size of the corner portion 76b, with the light shield also be re-shaped to correspond in shape to the gate electrode (again excluding the spur 76c). This implementation of the invention thus increases the light shield to gate electrode capacitive coupling, which has the same effect of reducing the capacitive coupling effect to the drain electrode. This approach increases the size of the gate overlap portion as defined above.

This approach has been found to provide significant improvement when at least ⅔ of the area of the light shield comprises the gate overlap portion.

This ratio may of course be increased further, for example the gate overlap portion can provide at least 80% or even 90% of the area of the light shield. The particular dimensions chosen will again depend on the available layout space and the desired operating characteristics.

Based on the intended use of a transistor in operation of the circuit of which it forms part, it is possible to predict the way the transistor will be biased, and this information can be used to determine the appropriate way to implement the invention. For a pixel transistor of an active matrix liquid crystal display, the TFT will experience biases in either direction, as a result of the polarity inversion scheme typically applied. Driver circuit transistors will instead be designed to operate in one bias direction only. Thus, for AMLCD driver circuitry TFTs, extra capacitance to either the gate or source (or drain) may be used, but for pixel TFTs, additional capacitive coupling to the gate is appropriate.

FIG. 11 shows some test results of source-drain current versus gate voltage, comparing conventional transistor designs of FIG. 6 (plot 110) and transistor designs of FIG. 10 (plot 112) with increased gate coupling, for operation with high drain bias resulting from 30V drain-source voltage.

The increase in capacitive coupling to the gate electrode reduces the leakage current, namely the current flowing for negative gate voltages.

The use of a significant capacitive coupling to the gate is very effective in reducing the TFT leakage at high drain biases. There is also an improvement in the TFT on current by 10-20%. This occurs because the light shield potential substantially follows the gate potential, and so the TFT can be considered to operate as a dual-gated TFT, with both top and bottom gates.

One issue with this implementation is that it can lead to an increase of circuit area. The applicability will therefore depend on the particular application. In some situations, for example with in-pixel TFTs, the light shield can be extended under an existing row electrode at no penalty to the pixel aperture, giving improved TFT performance compared to a conventional pixel TFT design.

FIG. 12 shows how the space beneath a row conductor (which connects to the transistor gate) can be used to enable the increase in capacitive coupling without loss of pixel aperture.

FIG. 12 shows an example of top gate TFT, viewed through the underlying substrate. The first layer seen (namely the bottom layer) is the layer defining the columns 120, the pixel electrode 128 and the source and drain terminals. The silicon island 122 overlies the source and drain with the row conductor 121 on top. The light shield layer conventionally has the shape shown as 124, but this can be extended to increase the gate overlap area to the shape 126, without loss of pixel aperture. A similar result can of course be obtained with a bottom gate structure.

FIG. 13 is used to explain another benefit which can be achieved by using capacitive coupling of the floating light shield, and which is of particular interest for transistors used in row (gate) driver circuits.

FIG. 13 shows a known high impedance gate driver circuit suitable for use in amorphous silicon active matrix liquid crystal displays (AMLCDs). The circuit shown is a single stage of a multiple stage shift register, with each stage being used to supply a row voltage pulse to one row of pixels. A similar circuit has been described in U.S. Pat. No. 6,052,426.

The circuit comprises an output drive transistor T_{drive} coupled between a clocked power line Pₙ and the row conductor Rₙ which is controlled by the stage. The clocked power line (and the complementary signal invPₙ) is a two phase signal, and the cycles of the clocked power line determine the timing of the sequential operation of the shift register stages.

The row pulse on the previous row Rₙ₋₁ is used to charge the output transistor gate through a diode-connected input transistor Tᵢₙ₂.

A first capacitor C₁ is connected between the output transistor gate and the control line which carries the complementary signal to the clocked power line Pₙ and the purpose of the capacitor C₁ is to offset the effects of internal parasitic capacitances of the output transistor.

An additional bootstrapping capacitor C₂ is provided between the gate of the output transistor and the row conductor (i.e. the output of the stage).

The stage is also controlled by the row pulse on the next row Rₙ₊₁, which is used to turn off the stage by pulling down the gate voltage of the output transistor. The row pulse on the next row Rₙ₊₁ is provided to the gate of the output transistor through an input transistor Tᵣ₍ₙ₊₁₎ associated with the next row conductor signal.

The circuit also has two reset transistors Tᵣ₋ₙ and Tᵣ₋ᵣ which are used when initially powering the circuit.

In operation, the input transistor Tᵢₙ₁ charges the output transistor gate during the previous row pulse. During this previous row pulse, the power line Pₙ is low and the inverse power line invPₙ is high. The output transistor is turned on by this previous row pulse, but as the power line Pₙ is low, the output of the stage remains low.

During this charging stage, the bootstrapping capacitor C₂ is charged to the row voltage pulse (less the threshold voltage of the input transistor Tᵢₙ₁).

During the next clock cycle, the clock signal Pₙ is high, and this increase in voltage pulls up the output voltage on the row conductor Rₙ through the output transistor. The effect of the bootstrapping capacitor C₂ is to increase the gate voltage to ensure that the full voltage level of the clocked signal Pₙ is passed to the row conductor Rₙ. The transistor Tᵣ₍ₙ₊₁₎ subsequently resets the output transistor gate voltage node during the next row pulse.

In the idle state, the coupling of the inverse power line invPₙ through the first capacitor C₁ is designed to prevent the output transistor gate from turning on when the output transistor T_{drive} receives a pulse from Pₙ.

The operation of the circuit as described above will be known to those skilled in the art. There are modifications and variations to this circuit, but these are not relevant to this invention.

The output low voltage of this type of high impedance row driver circuit can drift up by a few volts, because the clock pulses (on Pn) are still being supplied to the drive transistor (which is turned off), and so some charge can leak to the isolated row conductor output due to the high drain bias. It is leakage through the drive TFT which can cause the voltage drift. This can be reduced by coupling the light shield to the gate, as explained above. In particular, a large light shield overlap on the row side (namely on the gate and/or source terminals) enables the leakage from high clock pulses to be reduced, and also beneficially increases the leakage from the row to the clock low state, which is when the row is at a higher voltage than the signal on Pn. This gives improved control of the row voltage when it is isolated, and then enables the clock duty cycle to be increased. It also enables a reduction in the number of clock phases.

This can use no extra area, as the area of the bootstrap capacitor C2 is just reused, by extending the light shield under it. Depending on the physical arrangement of the layers forming the bootstrap capacitor, the bottom terminal is either connected to the gate or source of the output transistor.

FIG. 14 shows as plot 140 the leakage current through a conventional n-type TFT with a 30V drain voltage. The graph shows the leakage current versus gate voltage. The effect of increasing the light shield overlap to the source terminal, using the bootstrap capacitor, is shown as plot 144. As shown, there is a significant reduction in leakage current.

FIG. 15 shows the same transistor as FIG. 14, with increased light shield overlap to the source, and shows the operation in two different bias conditions. Plot 152 correspond to the plot 144 of FIG. 14, although modeled with a different drain voltage of 10V. Plot 156 shows the effect of reversing the direction of operation of the transistor, and shows that in the opposite direction, the leakage current is increased.

By coupling the light shield to the higher voltage terminal (out of the source and drain terminals) the leakage current is increased, for example by a factor of around 20. The output of the drive transistor will be the higher voltage terminal when the clock signal Pn is low, and this increased leakage current thus pulls the output voltage down. The clock signal Pn will be the higher voltage terminal when the clock signal Pn is high, and the increased coupling to the gate or source then prevents the output voltage being pulled up.

The different bias directions thus correspond to the different clock phases being applied to the transistor when turned off. This asymmetry enables the row voltage to be kept low when the transistor is isolated for both clock signal values.

It will be apparent that the invention can be applied to pixel circuits as wells as to transistors used in drive circuitry, for example row driver circuitry.

The invention can be applied to one or more transistors in the row driver circuit, and the invention may not be applied only to the output drive transistors. Where possible, the existing structure can be used to provide the additional overlap area, without needing to use additional area. For example, the use of the bootstrap capacitor to provide this possibility is one example.

FIG. 16 shows an active matrix liquid crystal display device comprising a display array 160 of pixels 162. The substrate 168 of the pixel array also carries row driver circuitry 164 and column driver circuitry 166. Additional circuitry 170 is provided off the substrate. The invention can be applied to the transistors in the pixel circuits and/or the row or column driver circuitry, as these will each be exposed to the backlight illumination. The backlight is shown as 172.

The invention has been described in detail in connection with displays, particularly backlit displays. However, the invention can be used in any application where light shielding is desired, including shielding from ambient light.

Many different types of transistor can be modified to provide the structure of the invention, including amorphous silicon top gated TFTs used in transmissive or transflective AMLCDs, amorphous silicon bottom gated TFTs, for example as used in flat x-ray image sensors, and also low temperature polysilicon transistor displays.

The definition of source and drain terminals is somewhat arbitrary, as one physical terminal can perform either function depending on the bias. What is important is the voltage bias on the terminals, and the capacitive coupling of the floating light shield electrode to these different voltage bias conditions in use.

In some of the examples above, the source overlap area is increased. However, depending on the circuit operation and the transistor type, this aspect of the invention may be considered more generally as the making one of the source and drain overlap portions have more than 1.5 times the area of the other. The larger area overlap will be dominate the capacitive coupling to the light shield, and the voltages on the transistor terminals as well as the operation of the circuit of which the transistor forms part will determine which is the appropriate terminal to capacitively couple to the light shield.

Only one specific example has been given above. It will be appreciated that the materials used to form the various layers are conventional. The processing conditions as well as various optional additional layers to those shown in the specific example, will be apparent to those skilled in the art.

Various other modifications will be apparent to those skilled in the art.

1. A thin film circuit comprising a plurality of thin film transistors, a plurality of the thin film transistors each comprising:
a transistor channel (74);
a gate electrode (76) aligned with the channel;
source (72) and drain (70) electrodes; and
an electrically floating-light shield portion (60) aligned with the transistor channel (74), the gate electrode (76) and the light shield portion (60) being located on opposite sides of the transistor channel (74),
wherein the light shield portion (60) is electrically isolated from the source (72), drain (70) and gate (76) electrodes, and wherein the light shield portion comprises a first, drain overlap portion in which the light shield portion overlaps the drain conductor (70), a second, source overlap portion in which the light shield portion overlaps the source conductor (72), and a third, gate overlap portion in which the light shield portion overlaps the gate conductor (76) only,
and wherein at least ⅔ of the light shield portion area comprises the gate overlap portion.

2. A thin film circuit as claimed in claim 1, wherein at least 80% of the light shield portion area comprises the gate overlap portion.

3. A thin film circuit as claimed in claim 2, wherein at least 90% of the light shield portion area comprises the gate overlap portion.

4. A thin film circuit comprising a plurality of thin film transistors, a plurality of the thin film transistors each comprising:
a transistor channel (74);
a gate electrode (76) aligned with the channel;
source (72) and drain (70) electrodes; and
an electrically floating-light shield portion (60) aligned with the transistor channel (74), the gate electrode (76) and the light shield portion (60) being located on opposite sides of the transistor channel (74),
wherein the light shield portion (60) is electrically isolated from the source (72), drain (70) and gate (76) electrodes, and wherein the light shield portion comprises a first, drain overlap portion in which the light shield portion overlaps the drain conductor, a second, source overlap portion in which the light shield portion overlaps the source conductor, and a third, gate overlap portion in which the light shield portion overlaps the gate conductor only,
and wherein one of the source and drain overlap portions has at least 1.5 times the area of the other of the source and drain overlap portions.

5. A thin film circuit as claimed in claim 4, wherein the source overlap portion is at least 1.5 times larger than the drain overlap portion.

6. A thin film circuit as claimed in claim 5, wherein the source overlap portion is at least 2 times larger than the drain overlap portion.

7. A thin film circuit as claimed in claim 1, wherein each of the plurality of thin film transistors comprises a top gate transistor, with the light shield portion (60) beneath the transistor channel (74).

8. A thin film circuit as claimed in claim 1, wherein each of the plurality of thin film transistors comprises a bottom gate transistor, with the light shield portion (60) above the transistor channel (74).

9. A thin film circuit as claimed in claim 1, wherein each of the plurality of thin film transistors comprises an amorphous silicon transistor.

10. A thin film circuit as claimed in claim 1, comprising an array of active matrix pixel circuits (162) provided on a common substrate, each pixel circuit comprising at least one of the plurality of the thin film transistors.

11. A thin film circuit as claimed in claim 1, comprising drive circuitry (164) for an array of active matrix pixel circuits, wherein the drive circuitry comprises one of more of the plurality of the thin film transistors.

12. A thin film circuit as claimed in claim 11, wherein the drive circuitry comprises row driver circuitry (164) having a plurality of row driver circuit portions, and wherein an output transistor (T_{drive}) of each of the row driver circuit portions comprises one of the plurality of the thin film transistors.

13. An active matrix display device comprising a thin film circuit as claimed in claim 1 carrying an array of display circuit pixels (162).

14. A display device as claimed in claim 13, comprising a backlight (172) for illuminating the display through the substrate.
